(19) United States
(12) Patent Application Publication
(10) Pub. No.: US 2026/0173298 A1
(43) Pub. Date: Jun. 18, 2026

(54) ADAPTIVE SHELVING FOR DEPLOYMENT OF NON-STANDARD INFORMATION TECHNOLOGY (IT) IN STANDARD RACKS

(71) Applicant: OpenAI OpCo, LLC., San Francisco, CA (US)

(72) Inventors: Chian-min Richard Ho, Palo Alto, CA (US); Reza Haji Aghaee Khiabani, San Mateo, CA (US)

(73) Assignee: OpenAI OpCo, LLC., San Francisco, CA (US)

(21) Appl. No.: 18/978,465

(22) Filed: Dec. 12, 2024

(51) Int. Cl. H05K 7/14; H05K 7/20

(52) U.S. Cl. CPC H05K 7/1489; H05K 7/1492; H05K 7/20272; H05K 7/20781

(57) ABSTRACT

The technology is a chassis adapter to adopt a standardized rack (e.g., a 19-inch rack) to accommodate non-standard components/equipment. The chassis adapter includes a housing that attaches to the standardized rack, and the housing has an interior space in which components are mounted. Reconfigurable members can be adjustably fixed to the interior walls of the housing, such that the attachment position on the walls is adjusted according to the dimensions of the components mounted thereto, allowing components with non-standard dimensions to be mounted within the standardized rack. For example, the components can be stacked vertically within the adaptive chassis with their long axis in the vertical direction. The reconfigurable members can be cantilevered, extend from one wall to another wall, and the reconfigurable members can include guides into which the components slide and the positions of the guides along the reconfigurable members can be adjusted.

### BACKGROUND

A 19-inch rack is a standardized frame or enclosure for mounting multiple electronic equipment modules. Each module has a front panel that is 19 inches wide. The 19-inch dimension includes the edges or ears that protrude from each side of the equipment, allowing the module to be fastened to the rack frame with screws or bolts. Common uses include computer servers, telecommunications equipment and networking hardware, audiovisual production gear, professional audio equipment, and scientific equipment.

The height of the electronic modules is also standardized as multiples of 1.75 inches (44.45 mm) or one rack unit or U. The industry-standard rack cabinet is 42 U tall. The 19-inch rack format with rack-units of 1.75 inches (44.45 mm) was established as a standard by AT&T around 1922. By 1934, the standard for 19-inch racks had evolved to include holes tapped for 12-24 screws with alternating spacings of 1.25 inches (31.75 mm) and 0.5 inches (12.70 mm). The standard (i.e., Electronic Industries Association (EIA) standard EIA-310) was revised in 1992, setting the standard U as 0.625 in+0.625 in+0.500 in, making each U 1.75 in. Since then, the 19-inch rack format has remained constant while the technology that is mounted within it has changed and the set of fields to which racks are applied has expanded.

Open Rack is an Open Compute Project standard for a new rack and power delivery architecture that is an alternative to the EIA-310 19-inch rack. The Open Rack standard was designed specifically for large-scale cloud deployments. There are four primary differences between the Open Rack standard and the traditional EIA-310 standard. First, the power to the compute, storage, or network devices is supplied by a pair of bus bars located in the rear of the rack. Second, the bus bars are supplied with 48 V DC by a shelf of power supplies. Third, the information technology (IT) equipment that fits into Open Rack is 21 inches or 533 millimeters wide. Fourth, the vertical spacing is greater.

### BRIEF DESCRIPTION OF THE SEVERAL VIEWS OF THE DRAWINGS

Details of one or more aspects of the subject matter described in this disclosure are set forth in the accompanying drawings and the description below. However, the accompanying drawings illustrate only some typical aspects of this disclosure and are therefore not to be considered limiting of its scope. Other features, aspects, and advantages will become apparent from the description, the drawings, and the claims.

FIG. 1A illustrates an exploded view of an example of a standardized rack in accordance with some embodiments.

FIG. 1B illustrates an assembled view of an example of a standardized rack in accordance with some embodiments.

FIG. 2A illustrates an example of an adaptive chassis mounted in a standardized rack in accordance with some embodiments.

FIG. 2B illustrates an example of an adaptive chassis mounted in a frame of a standardized rack with side doors removed, in accordance with some embodiments.

FIG. 3A illustrates an example of an example of an adaptive chassis in accordance with some embodiments.

FIG. 3B illustrates an example of reconfigurable members in accordance with some embodiments.

FIG. 3C illustrates an example of guide members in accordance with some embodiments.

FIG. 4A illustrates a first example of reconfigurable members being adjustably mounted in an adaptive chassis in accordance with some embodiments.

FIG. 4B illustrates a first example of guide members being adjustably mounted in an adaptive chassis, in accordance with some embodiments.

FIG. 4C illustrates a first example of a first set of components being mounted to an adaptive chassis via reconfigurable members and guide members, in accordance with some embodiments.

FIG. 4D illustrates a first example of a second set of components being mounted to an adaptive chassis in accordance with some embodiments.

FIG. 4E illustrates a first example of an adaptive chassis being mounted in a standardized rack in accordance with some embodiments.

FIG. 4F illustrates a second example of an adaptive chassis being mounted in a standardized rack in accordance with some embodiments.

FIG. 5 illustrates a method 500 for using a chassis adapter to adapt a standardized rack in accordance with some embodiments.

FIG. 6A illustrates a second example of reconfigurable members being adjustably mounted in an adaptive chassis in accordance with some embodiments.

FIG. 6B illustrates a second example of guide members being adjustably mounted in an adaptive chassis in accordance with some embodiments.

FIG. 6C illustrates a second example of a first set and a second set of components being mounted to an adaptive chassis in accordance with some embodiments.

FIG. 6D illustrates a second example of a third set of components being mounted to an adaptive chassis in accordance with some embodiments.

FIG. 6E illustrates an alternative configuration of reconfigurable members for the second example in accordance with some embodiments.

FIG. 7A illustrates an exploded view of a third example of an adaptive chassis in which the reconfigurable members include dog legs, in accordance with some embodiments.

FIG. 7B illustrates a perspective view of a third example of an adaptive chassis in accordance with some embodiments.

FIG. 7C illustrates a front view of a third example of an adaptive chassis in accordance with some embodiments.

FIG. 7D illustrates a third example with components mounted in an adaptive chassis in accordance with some embodiments.

FIG. 7E illustrates a third example of an adaptive chassis being mounted in a standardized rack in accordance with some embodiments.

FIG. 8A illustrates an example of a standardized rack, including an electric busbar and a coolant manifold in accordance with some embodiments.

FIG. 8B illustrates a first view of an adaptive chassis that includes an electric busbar and a coolant manifold in accordance with some embodiments.

FIG. 8C illustrates a second view of an adaptive chassis that includes an electric busbar and a coolant manifold in accordance with some embodiments.

FIG. 9A illustrates an example of an adaptive chassis in which an irregularly shaped component has been mounted in accordance with some embodiments.

FIG. 9B illustrates an example of an adaptive chassis in which a component has been mounted in an irregular configuration in accordance with some embodiments.

FIG. 10A illustrates an example of an adaptive chassis in which the reconfigurable members and guide members are configured for horizontally aligned components in accordance with some embodiments.

FIG. 10B illustrates an example of an adaptive chassis in which the reconfigurable members and guide members are configured for mixed horizontally and vertically aligned components in accordance with some embodiments.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

Server racks have been standardized, which allows equipment providers who comply with the standard to supply equipment that is ensured to be compatible with the customer's server rack. However, standard rack dimensions can cause signal integrity issues. For example, the standard rack dimensions can constrain the placement of server/computational components to be spaced farther apart than the specified transmission distance of the signal drivers in the server components. Consequently, the signals may be too attenuated to ensure reliable operation. Additionally, as server requirements change, it may be beneficial to accommodate more variety in server dimensions. The adaptive shelving disclosed herein addresses this issue by using an adaptive chassis insert to the standard server rack thereby removing constraints on how respective components can be arranged. For example, in certain circumstances, by arranging components vertically, rather than horizontally, the communication distance between components can be reduced, thereby improving signal integrity.

For example, an optimal arrangement of two standard-width components may be to place the components side-by-side. While this could be achieved using a custom double-width rack, a better and simpler approach can be to align the components vertically (i.e., the long axis in the vertical direction) and stack the components side-by-side in the vertical direction. Such an arrangement is not accommodated by standardized racks. Further, conventional chassis are not reconfigurable to enable such an arrangement. Accordingly, the systems and methods disclosed herein provide an adaptive chassis that can accommodate mounting components in non-standard configurations. Additionally or alternatively, the systems and methods disclosed herein provide an adaptive chassis that can accommodate mounting components having non-standard dimensions.

The Open Rack from the Open Compute Project standard and the standardized 19-inch rack discussed above provide two non-limiting examples of the types of racks with which the adaptive chassis disclosed herein can be used. Persons skilled in the relevant art can appreciate that the adaptive chassis disclosed herein can be used with other types of racks, including existing and future rack standards. Further, persons skilled in the relevant art can appreciate that many modifications and variations are possible in light of this disclosure.

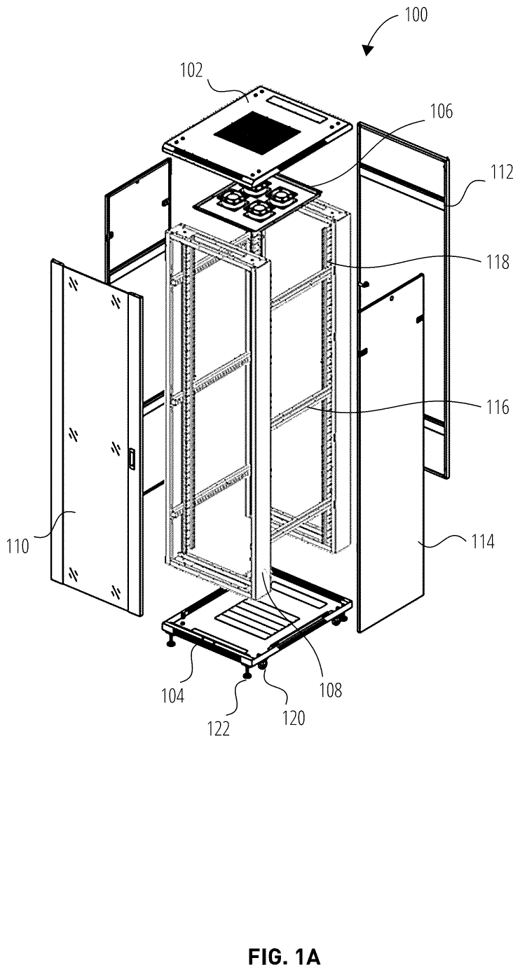

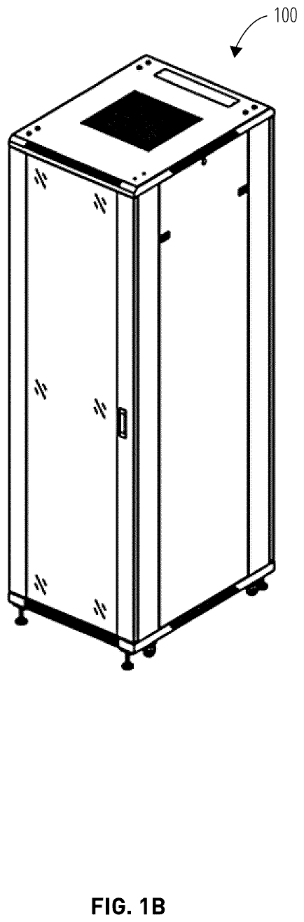

FIG. 1A and FIG. 1B show standardized rack 100. FIG. 1A shows an exploded view of standardized rack 100. FIG. 1B shows an assembled view of standardized rack 100. Standardized rack 100 includes top cover 102, bottom 104, fan plate 106, frames 108, front door 110, back door 112, side doors 114, horizontal bracing 116, columns 118, castors 120, and feet 122. For example, standardized rack 100 can be an EIA-310 19-inch rack that is configured to house various electronic equipment, including servers, networking devices, etc.

The rack framework includes frames 108 and horizontal bracing 116. Frames 108 can be vertical rails that are made of steel or aluminum and support the equipment/components mounted thereon. Frames 108 can be spaced to accommodate devices designed for a 19-inch width. Horizontal bracing 116 connects the vertical rails and provides additional stability. Rack space can be measured in “U,” where 1 U equals 1.75 inches in height. Equipment/components that are standardized can be described in terms of how many rack units it occupies (e.g., a 1 U server). Column 118 can be mounting brackets that provide attachment points, allowing equipment to be securely attached to the vertical rails. Front door 110 and back door 112 can be removable or lockable. These doors can be solid or mesh for airflow, and they can protect equipment while allowing access. Similarly, side doors 114 can also be removable or lockable. Further, side doors 114 can be used to maintain security and improve airflow. According to certain non-limiting examples, side doors 114 can be vented for additional cooling. According to certain non-limiting examples, standardized rack 100 can be equipped with castors 120 (e.g., wheels) for easy movement and have adjustable feet (e.g., feet 122) for stability and prevent movement once standardized rack 100 has been located at its desired location.

According to certain non-limiting examples, standardized rack 100 can include an electric busbar and/or a coolant manifold. For example, the electric busbar can include one or more power strips that distribute power to multiple devices housed in the rack. Further, the electric busbar can provide surge protection and remote management capabilities. The coolant manifold can be part of a cooling solution that includes fans and vents to maintain airflow and prevent equipment from overheating. Additionally, cooling units can be integrated with standardized rack 100 to provide additional cooling in dense configurations. For example, a cooling unit can provide coolant to coolant manifold, which has ports to provide the coolant to the equipment/components mounted on standardized rack 100.

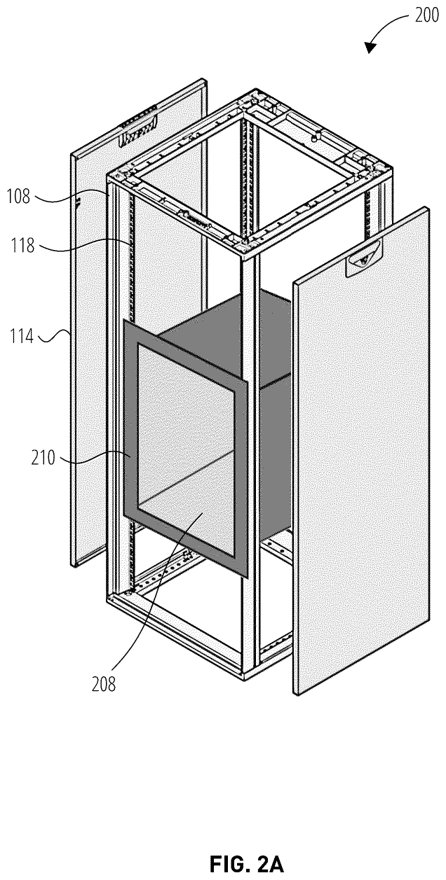

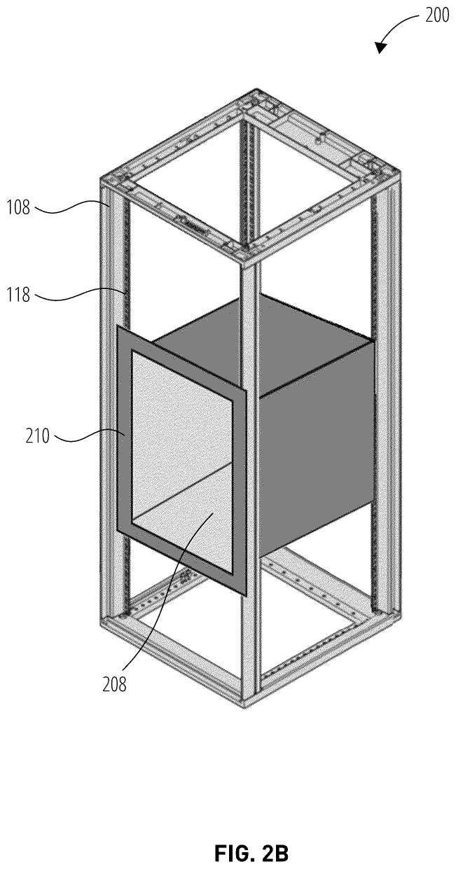

FIG. 2A and FIG. 2B show respective views of adaptive chassis 208 being mounted to standardized rack 100 to provide rack-chassis system 200. Adaptive chassis 208 includes flange 210, which has attachment points for connecting to column 118. According to certain non-limiting examples, adaptive chassis 208 can include flange 210 at the front and another flange at the back, providing additional attachment points between standardized rack 100 and adaptive chassis 208 and allowing adaptive chassis 208 to support more weight.

Adaptive chassis 208 adapts standardized rack 100 to accommodate non-standard components (e.g., components having a size that is not an integer multiple of U) and/or to accommodate non-standard configurations for the components. For example, standard rack dimensions can cause signal integrity issues, providing motivation for adaptive chassis 208 that allows for non-standard components and configurations. In one case, the standard rack dimensions can constrain the placement of server components such that they are spaced farther apart than the specified transmission distance of the signal drivers in the server components. Consequently, when constrained by standard rack dimensions, the signals may be too attenuated to ensure reliable operation.

Adaptive chassis 208 addresses the above-noted signal integrity issue by, e.g., providing non-standard component configurations. According to certain non-limiting examples, adaptive chassis 208 can enable the arrangement of the components to be mounted vertically, rather than horizontally, such that the components can be stacked vertically with the long axis of the components in the vertical direction, reducing the communication distance between components, thereby improving signal integrity. Adaptive chassis 208 can be mounted to standardized rack 100 to enable such vertical mounting of components or other non-standard mounting arrangements, removing constraints on how respective components can be arranged.

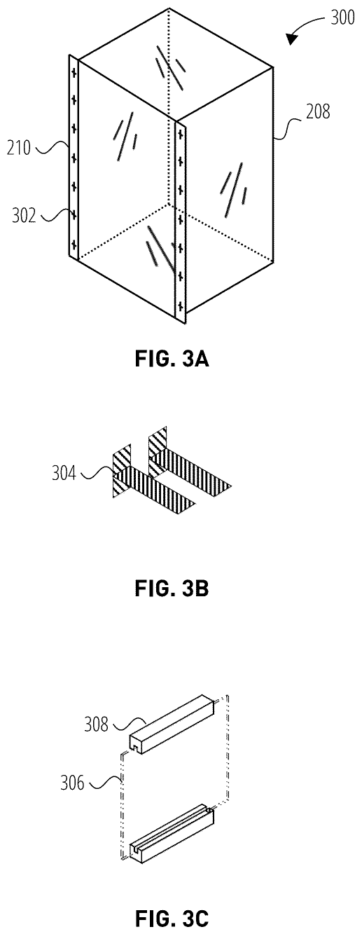

FIGS. 3A-3C show parts of adaptive-chassis system 300, which can be combined in various ways to provide flexibility for the size and arrangement of components in standardized rack 100. FIG. 3A shows adaptive chassis 208, which includes four side walls and a back. Alternatively, adaptive chassis 208 can include four side walls without a back. Adaptive-chassis system 300 includes attach points 302 for attaching adaptive chassis 208 to standardized rack 100.

According to certain non-limiting examples, a length of reconfigurable members 304 can be continuously adjustable (e.g., using a telescoping design) or discretely adjustable (e.g., by selecting building blocks for 304 of different lengths.

FIG. 3B shows reconfigurable members 304. Reconfigurable members 304 can be connected to the walls of adaptive chassis 208 at a plurality of heights along the wall to adapt to the dimensions of a particular component (e.g., the dimension of the width/long axis of the component), such that the component can be accommodated/mounted within the interior volume/space of adaptive chassis 208. According to certain non-limiting examples, reconfigurable members 304 can be mounted to the wall of adaptive chassis 208 at a plurality of discrete points along the vertical direction, including standard dimensions and non-standard dimensions. According to certain non-limiting examples, reconfigurable members 304 can be mounted to the wall of adaptive chassis 208 at a continuum of points along the vertical direction.

According to certain non-limiting examples, reconfigurable members 304 can be cantilevered. Alternatively, reconfigurable members 304 can extend across the width of the adaptive chassis 208 and are attachable to both side walls.

According to certain non-limiting examples, the rigidity of reconfigurable members 304 can be increased by using reinforcing members that are integrated with or attached to reconfigurable members 304. This increased rigidity can be provided by orthogonal flanges running the length of a reconfigurable member. For example, reconfigurable members 304 can be formed to have a cross-sectional shape of an I-beam. Alternatively, reconfigurable members 304 can be formed to have a T-shaped cross-section, a U-shaped cross-section, or an L-shaped cross-section. The increased rigidity of reconfigurable members 304 can mitigate buckling and/or sagging of the mounted components and can enable adaptive chassis 208 to support heavier loads. Additionally or alternatively, separate reinforcement structures, which are independent of reconfigurable members 304 can provide structural reinforcement within an interior space of adaptive chassis 208. Reinforcement structures can also be provided to the back wall or near the front opening of adaptive chassis 208.

FIG. 3C shows guide members 308, which can be used to guide the insertion of component 306 into adaptive chassis 208. Guide members 308 can be connected to reconfigurable members 304. Alternatively, reconfigurable members 304 and guide members 308 can integrated into a single unit.

The location along reconfigurable members 304 at which adaptive chassis 208 is connected can be adjusted to accommodate various dimensions of the components to be mounted thereto. According to certain non-limiting examples, guide members 308 can be attached to reconfigurable members 304 at a plurality of discrete points along the horizontal direction, including standard dimensions and non-standard dimensions. According to certain non-limiting examples, guide members 308 can be attached to reconfigurable members 304 at a continuum of points along the horizontal direction.

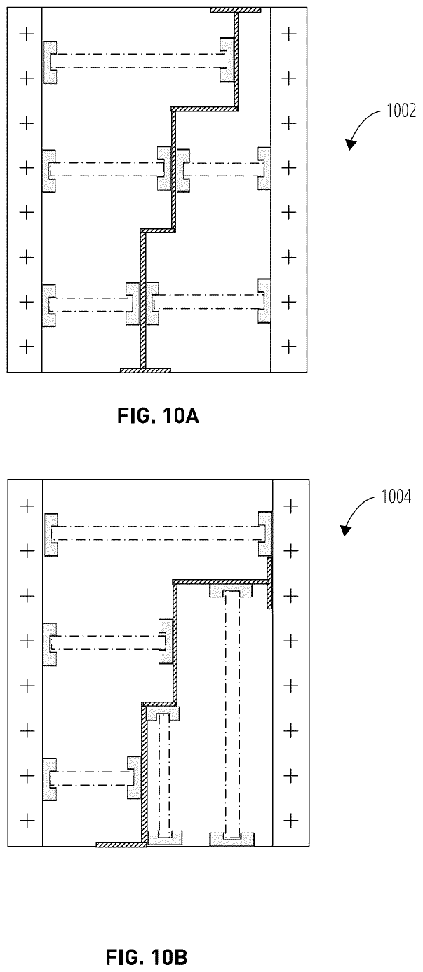

The combination of the adjustability for the position at which reconfigurable members 304 are mounted in the vertical direction together with the adjustability for the position at which guide members 308 are mounted in the horizontal direction can be used to accommodate components for various height and width dimensions. FIGS. 3A-3C show the configuration in which components are to be mounted with their long dimension (i.e., their width) along the vertical direction. Additionally or alternatively, reconfigurable members 304 and guide members 308 can be separable and can be rotated to mount their long dimension along the horizontal direction, as illustrated below in FIG. 10A.

According to certain non-limiting examples, reconfigurable members 304 and guide members 308 can be integrated. Alternatively, reconfigurable members 304 and guide members 308 can be separable.

According to certain non-limiting examples, different types of guide members 308 can be used for different components.

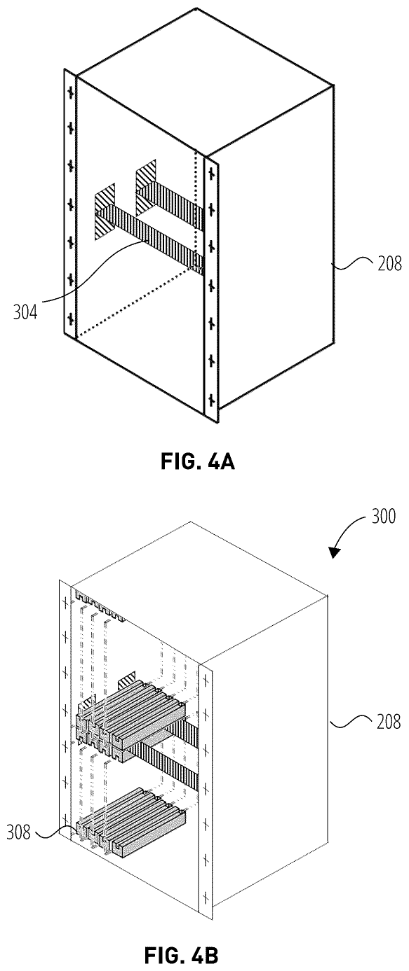

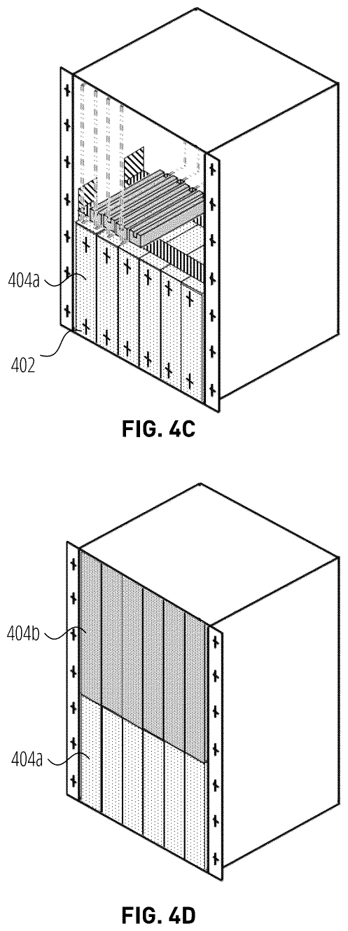

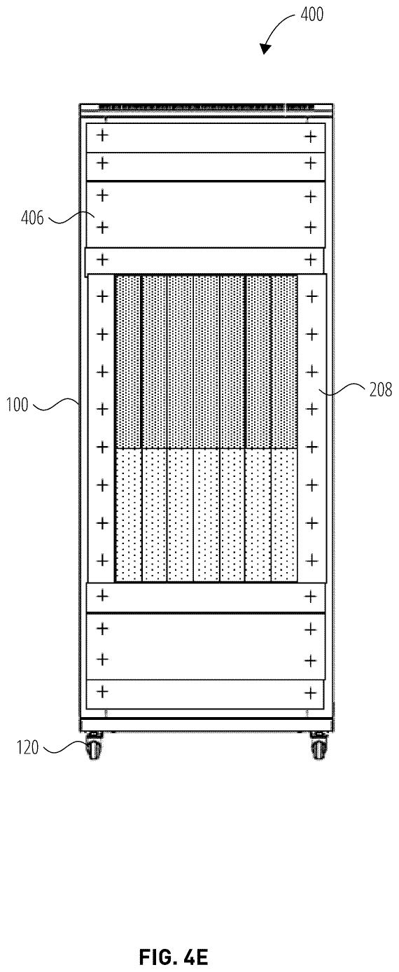

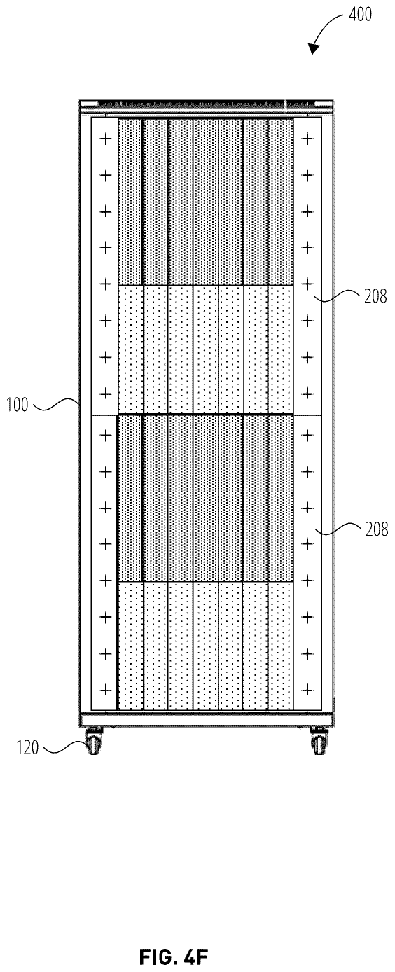

FIGS. 4A-G illustrates rack-chassis system 200 at various points during assembly. FIG. 4A shows adaptive chassis 208 with reconfigurable members 304 mounted at a desired height in the vertical direction. In FIG. 4A, reconfigurable members 304 extend from one side wall to the other side wall. Reconfigurable members 304 are fixed at particular vertical locations, which can be adjusted based on the dimensions of the components to be mounted.

Various mechanisms can be used to adjustably fix reconfigurable members 304 to the inner wall of adaptive chassis 208. By allowing the vertical position along the wall to be adjusted, reconfigurable members 304 can be reconfigured/adjusted to accommodate and mount components having non-standard dimensions.

According to certain non-limiting examples, the mechanism for fixing reconfigurable members 304 to the wall can enable continuous adjustment of the vertical position. A continuously adjustable attachment mechanism allows for fine-tuned or incremental adjustments, ensuring a secure and customizable connection.

Examples of continuous adjustable attachment mechanisms can include, e.g., a T-slot system, rack and pinion system with an adjustable guide, a linear actuator with a clamping mechanism, a spring-loaded pin and groove system, a scissor mechanism, a worm drive system, a turnbuckle system, a drum and cable system, a rail-slider system with locking mechanism. A T-slot system involves a groove that runs along a surface into which a corresponding T-shaped clamp or bolt can slide. The clamp is tightened to secure an attachment at any point along the groove. A rack and pinion system uses a toothed bar (referred to as the rack) and a gear (referred to as the pinion). The position of the pinion can be adjusted along the rack by rotating the gear, offering continuous adjustment for positioning. Linear actuators can be combined with a clamping mechanism to allow for precise adjustments along a track or groove. The actuator can move the clamping system into position, and then the clamp locks the attachment in place. A spring-loaded pin fits into a groove or a set of holes along a rail, and the spring helps hold the pin in place once it's engaged in the groove. The scissor mechanism is a mechanical linkage system used to create vertical motion or extension. It consists of a series of interconnected, folding supports that resemble the shape of a pair of scissors. A turnbuckle is a rigid body with two threaded ends and respective bolts at these threaded ends such that rotating the rigid body displaces one bolt relative to the other bolt (e.g., to tension a cable). A cable drum system (also referred to as a hoist) adjusts the height of an object fixed to one end of the cable by winding or unwinding the cable spooled around the drum.

Examples of discreetly adjustable attachment mechanisms can include, e.g., a ratcheting mechanism, a detent pin mechanism, a pin and hole adjustment, or an indexing plunger. A ratcheting system uses a gear and pawl mechanism that allows for incremental adjustments in one direction, such as in a come-along wench. The mechanism engages and clicks into predefined positions, and the mechanical member can be adjusted by a fixed increment each time the ratchet is advanced. A pin-and-hole adjustment system uses a pin that fits into a series of holes along a vertical rail or column. The pin is inserted into one of the holes to lock the position of the mechanical member at specific heights. To adjust the height, the pin is removed and placed into a different hole. An indexing plunger system uses an indexing plunger (e.g., a spring-loaded pin) that locks into predefined notches or holes along a track. Each notch or hole corresponds to a discrete height adjustment. The plunger locks into position when engaged, preventing movement until it is released. Similar to the indexing plunger, a detent pin is used in mechanisms where a ball or pin engages with a series of holes or notches in a component to provide discrete locking positions. Each detent position corresponds to a specific height or position.

FIG. 4B shows adaptive chassis 208 in which guide members 308 are connected to reconfigurable members 304. Guide members 308 are connected to reconfigurable members 304 at particular horizontal locations based on the dimensions of the components to be mounted.

FIG. 4C shows adaptive chassis 208 after a first set of components (i.e., components 404a) have been mounted to adaptive chassis 208 via reconfigurable members 304 and guide members 308.

FIG. 4D shows adaptive chassis 208 after a second set of components (i.e., components 404b) have been mounted to adaptive chassis 208 via reconfigurable members 304 and guide members 308.

FIG. 4E shows adaptive chassis 208 being mounted to standardized rack 100 to provide rack system 400. In addition to adaptive chassis 208, horizontally mounted components 406 are also shown to be mounted to standardized rack 100. Here, horizontally mounted components 406 are standard integer multiples of U (i.e., the rack unit).

Adaptive chassis 208 can be attached to standardized rack 100 at any point in the process of configuring standardized rack 100, including before or after components 404a and components 404b have been mounted.

FIG. 4F shows rack system 400 when two adaptive chassis 208 have been mounted to standardized rack 100 to provide rack system 400. Here, there are no horizontally mounted components 406.

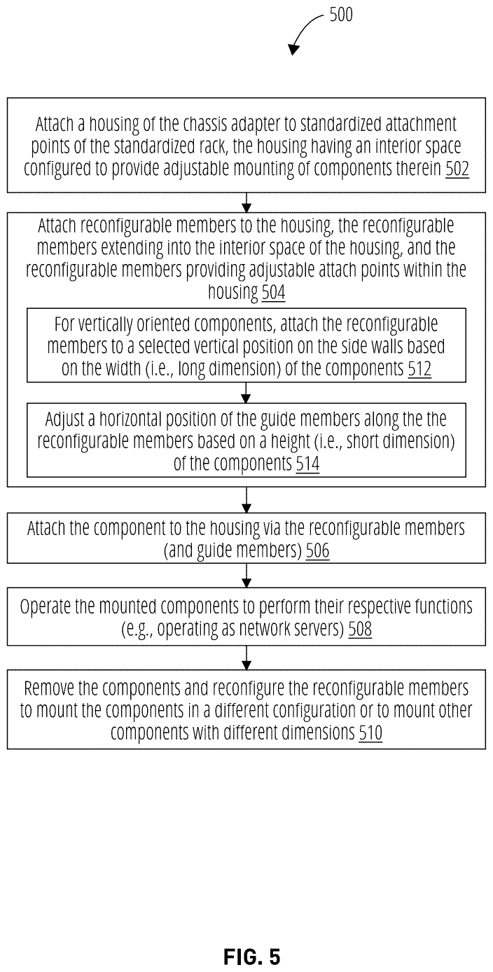

FIG. 5 illustrates an example method 500 for using a chassis adapter to adapt a standardized rack to accommodate non-standard component dimensions and/or non-standard component configurations. Although the example method 500 depicts a particular sequence of operations, the sequence may be altered without departing from the scope of the present disclosure. For example, some of the operations depicted may be performed in parallel or in a different sequence that does not materially affect the function of method 500. In other examples, different components of an example device or system that implements the method 500 may perform functions at substantially the same time or in a specific sequence.

According to some examples, the method includes attaching a housing of the chassis adapter to standardized attachment points of the standardized rack, the housing having an interior space configured to provide adjustable mounting of components therein at step 502. For example, as illustrated in FIG. 2A, adaptive chassis 208 may have a housing that is attached to standardized attachment points of standardized rack 100, and the housing has an interior space configured to provide adjustable mounting of components therein.

According to some examples, process 504 of the method includes attaching reconfigurable members to the housing, the reconfigurable members extending into the interior space of the housing, and the reconfigurable members providing adjustable attach points within the housing. For example, reconfigurable members 304 illustrated in FIG. 3B may be attached to the housing of adaptive chassis 208. As illustrated in FIG. 4A, reconfigurable members 304 can extend into the interior space of the housing, and the reconfigurable members can provide adjustable attach points within the housing for components (e.g., component 404a, component 404b, etc.).

Process 504 can include step 512 and step 514. In step 512, the method includes that, for vertically oriented components, the reconfigurable members are attached to selected vertical positions on the side walls, and these vertical positions are selected based on the width (i.e., long dimension) of the components. For example, reconfigurable members 304 illustrated in FIG. 3B may be attached to selected vertical positions on the side walls, which are selected based on the width (i.e., long dimension) of the components.

In step 514, the method includes adjusting a horizontal position of the guide members along the reconfigurable members based on a height (i.e., short dimension) of the components. For example, the horizontal positions of guide members 308 are illustrated in FIG. 3C may be adjusted such that a horizontal position of the guide members along the reconfigurable members is based on a height (i.e., short dimension) of the components.

According to some examples, the method includes attaching the component to the housing via the reconfigurable members (and guide members) at step 506. For example, component 404a illustrated in FIG. 4C may be attached to the housing via the reconfigurable members 304 and guide members 308.

According to some examples, the method includes operating the mounted components to perform their respective functions (e.g., operating as network servers) at block 508. For example, the mounted components of rack system 400 illustrated in FIG. 4E may operate to perform their respective functions (e.g., operating as network servers).

According to some examples, the method includes removing the components and reconfiguring the reconfigurable members to mount the components in a different configuration or to mount other components with different dimensions at block 510. For example, the components may be removed from adaptive chassis 208, and reconfigurable members 304 can be reconfigured to mount the components in a different configuration or to mount other components with different dimensions.

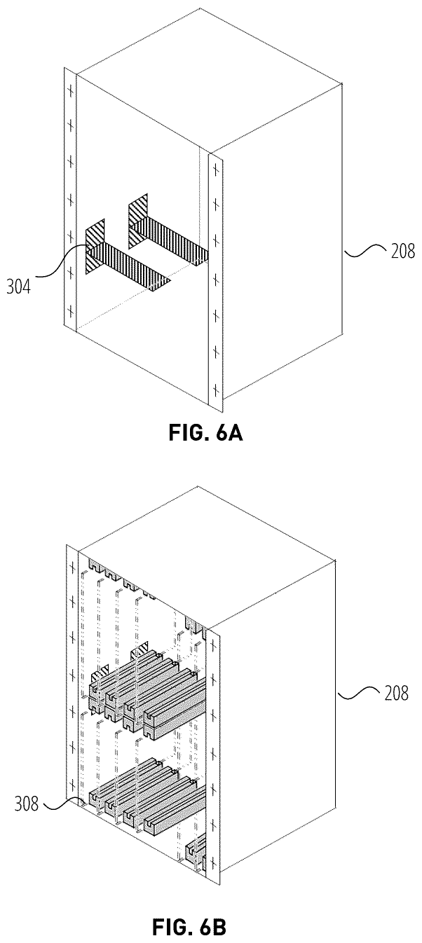

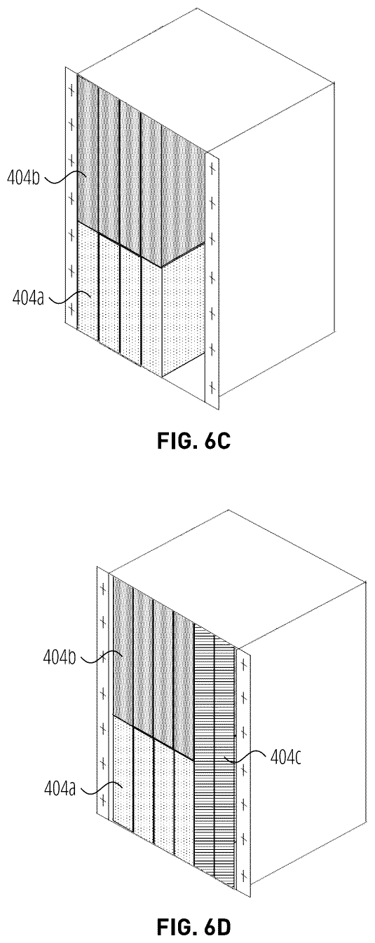

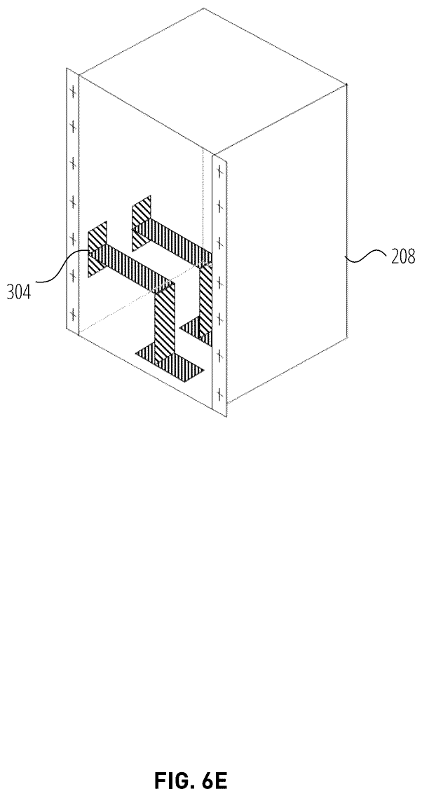

FIGS. 6A-E illustrates rack-chassis system 200 at various points during assembly. In this case, three different component sizes are accommodated. To accomplish this, reconfigurable members 304 are cantilevered, rather than extending across the width of adaptive chassis 208 from one side wall to the other side wall.

FIG. 6B shows adaptive chassis 208 in which guide members 308 are connected to reconfigurable members 304. Guide members 308 are connected to reconfigurable members 304 at particular horizontal locations based on the dimensions of the components to be mounted.

FIG. 6C shows adaptive chassis 208 after the first and second set of components (i.e., components 404a and components 404b) have been mounted to adaptive chassis 208 via reconfigurable members 304 and guide members 308.

FIG. 6D shows adaptive chassis 208 after a third set of components (i.e., components 404c) have been mounted to adaptive chassis 208 via reconfigurable members 304 and guide members 308.

FIG. 6E shows an alternative configuration for reconfigurable members 304 and adaptive chassis 208 in which reconfigurable members 304 are attached to a side wall and a bottom wall of adaptive chassis 208.

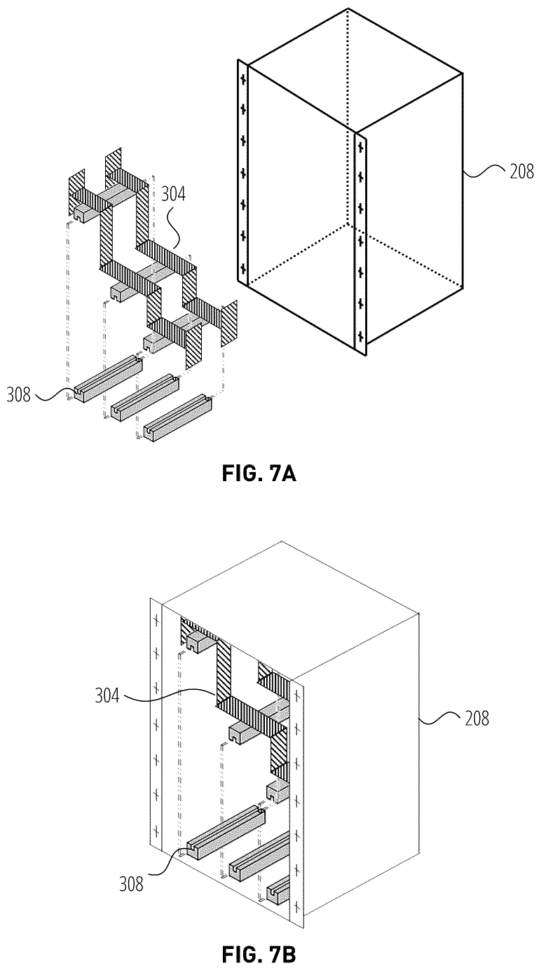

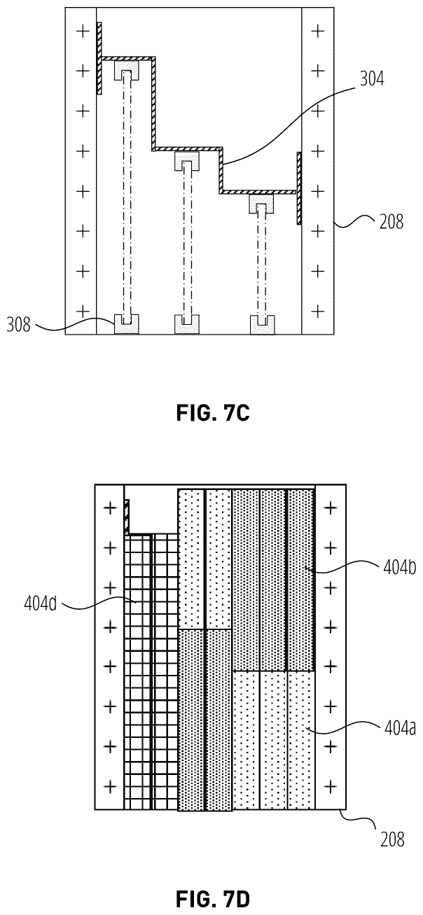

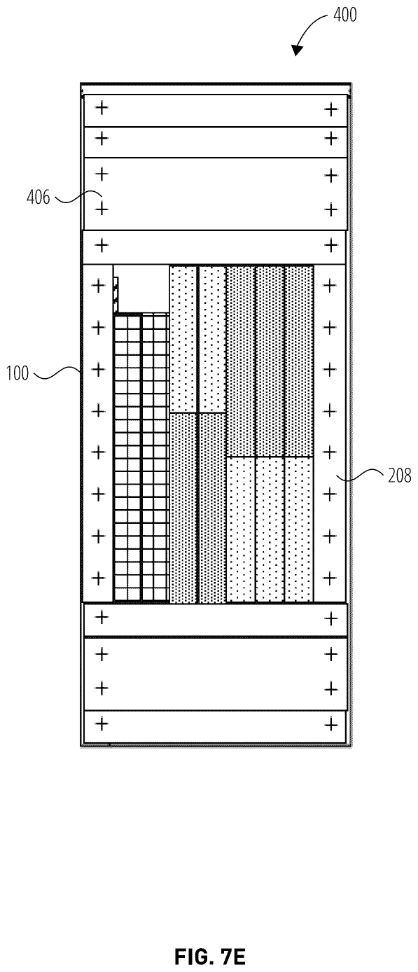

FIGS. 7A-E illustrates rack-chassis system 200 at various points during assembly. In this case, various components having many different dimensions can be mounted, and reconfigurable members 304 can have one or more dog legs to achieve this. FIG. 7A shows an exploded view in which the dog legs in reconfigurable members 304 can be seen and guide members 308 are arranged to accommodate three different component widths.

FIG. 7B shows a perspective view in which reconfigurable members 304 and guide members 308 have been assembled with adaptive chassis 208.

FIG. 7C shows a front view of reconfigurable members 304 and guide members 308 assembled with adaptive chassis 208.

FIG. 7D shows a perspective view in which reconfigurable members 304 and guide members 308 have been assembled with adaptive chassis 208.

FIG. 7E shows rack system 400 in which adaptive chassis 208 with the configuration shown in FIG. 7D has been mounted. Similar to FIG. 4E, adaptive chassis 208 is mounted in standardized rack 100 together with horizontally mounted components 406.

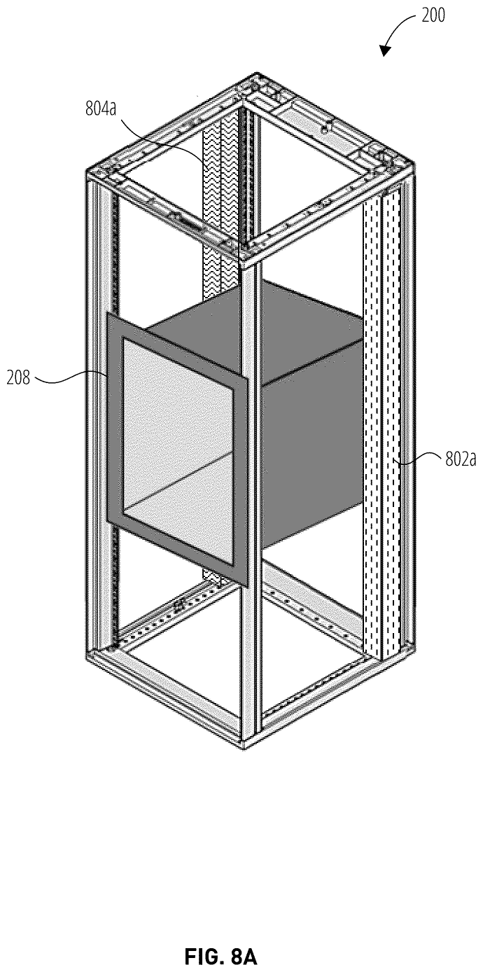

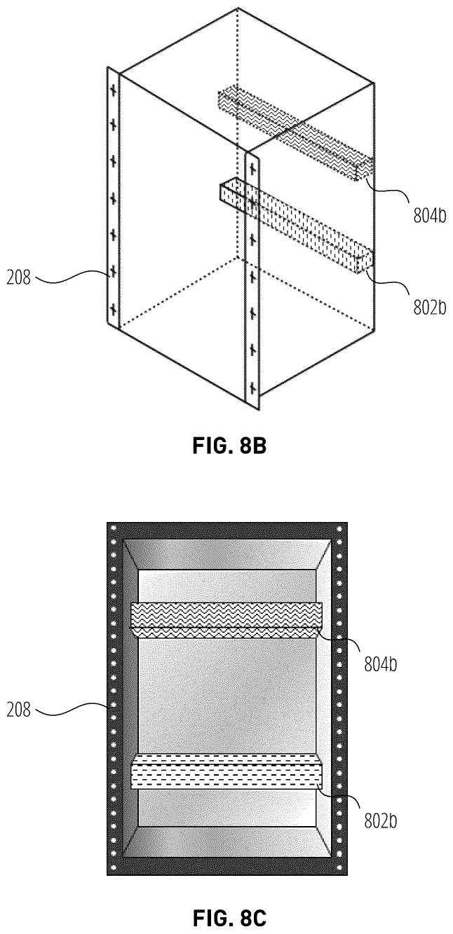

FIG. 8A shows an example of rack-chassis system 200 in which standardized rack 100 includes coolant manifold 802a and electric busbar 804a. Coolant manifold 802a and electric busbar 804a can be oriented vertically in standardized rack 100 to provide cooling and electrical power to rack units/equipment mounted horizontally to standardized rack 100.

For example, electric busbar 804a can include a series of standard electrical plugs/receptacles into which electrical cords can be pugged to provide electric power to rack units/equipment.

Similarly, coolant manifold 802a can provide a fluid path from a coolant distribution unit (CDU) to fluid couplings. Tubing from equipment mounted on the rack can be connected to the fluid couplings of coolant manifold 802a to provide coolant to the rack-mounted equipment. The fluid couplings on coolant manifold 802a can use various types of couplings. Examples of fluid coupling types can include, e.g., push-fit connectors, camlock couplings, quick-release clips, quick-disconnect fittings, etc.

FIG. 8B and FIG. 8C show examples of adaptive chassis 208 including coolant manifold 802b and electric busbar 804b. For example, coolant manifold 802b and electric busbar 804b can each be oriented horizontally in adaptive chassis 208 to provide cooling and electrical power to rack units/equipment mounted vertically within adaptive chassis 208. Electric busbar 804a can include a series of electrical plugs/receptacles into which electrical cords can be plugged to provide electric power to the components mounted within adaptive chassis 208. According to certain non-limiting examples, electric busbar 804b can plug into and receive electrical power from electric busbar 804a. Additionally or alternatively, electric busbar 804b can plug into and receive electrical power from a wall receptacle/plug.

Similarly, coolant manifold 802b can provide a fluid path from coolant manifold 802a to fluid couplings on coolant manifold 802b, such that tubing can be connected to the fluid couplings to provide coolant to the components mounted in adaptive chassis 208. According to certain non-limiting examples, coolant manifold 802b can connect to and receive coolant from coolant manifold 802a. Additionally or alternatively, coolant manifold 802b can connect to and receive coolant from a CDU. According to certain non-limiting examples, the fluid couplings on coolant manifold 802b can be the same type of couplings as the fluid couplings on coolant manifold 802a.

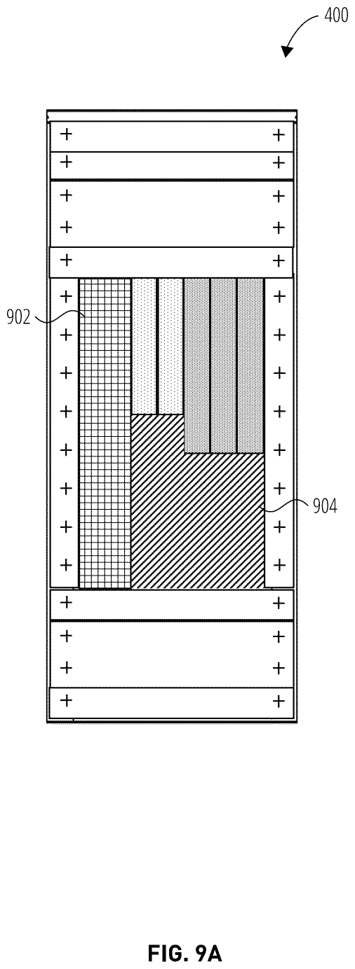

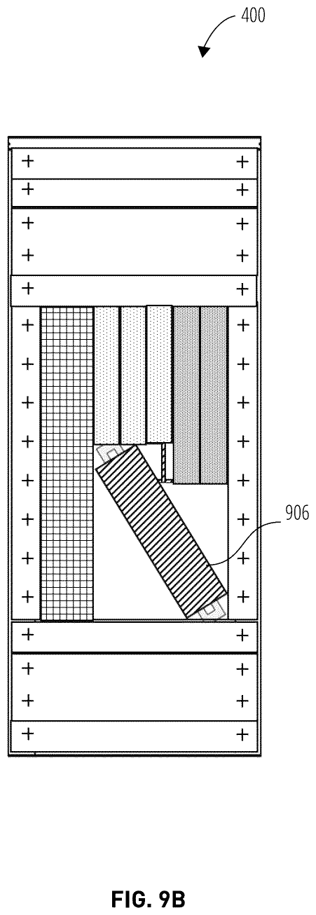

FIG. 9A shows an example in which rack system 400 includes irregular-shape component 904. That is, adaptive chassis 208 can be configured such that irregular-shape component 904 is mounted in adaptive chassis 208. In this case, irregular-shape component 904 is an irregular hexagon with only right angles. Adaptive chassis 208 can be adapted to accommodate components with arbitrary shapes, as long as the components fit within the interior area of adaptive chassis 208.

FIG. 9B shows an example in which rack system 400 includes angled component 906. That is, adaptive chassis 208 can be configured such that angled component 906 is mounted in adaptive chassis 208 with its long axis oriented at an angle with respect to both the horizontal direction and the vertical direction. For example, guide members 308 can be mounted to adaptive chassis 208 and/or reconfigurable members 304 using a wedge or an an angled bracket (e.g., a hinged bracket) that allows angled component 906 to be mounted at various angles with respect to adaptive chassis 208.

FIG. 10A shows an example of chassis with horizontal orientation configuration 1002. That is, the adaptive chassis has be configured with reconfigurable members 304 and guide members 308 such that the components can be mounted to the chassis with an orientation in which the long axis is in the horizontal direction.

FIG. 10B shows an example of chassis with mixed orientation configuration 1004. That is, the adaptive chassis has be configured with reconfigurable members 304 and guide members 308 such that some of the components can be mounted to the chassis with an orientation in which the long axis is in the horizontal direction and other of the components can be mounted to the chassis with an orientation in which the long axis is in the vertical direction.

### Aspects

The present technology includes computer-readable storage mediums for storing instructions, and systems for executing any one of the methods embodied in the instructions addressed in the aspects of the present technology presented below:
Clause 1. A chassis adapter for adapting a standardized rack, comprising: a housing that includes a front plate and an interior space, the front plate being configured to attach to standard-rack-unit-shelving attach points of the standardized data-center rack, and the interior space being configured to provide an adaptable arrangement for component mounting; and one or more reconfigurable members extending into the interior space of the housing, the one or more reconfigurable members providing adjustable attach points for a first component with respect to the housing, the first component being mounted in the interior space of the housing.
Clause 2. The chassis adapter of clause 1, wherein: the one or more reconfigurable members provide attach points for the first component to be vertically mounted in the interior space, the one or more reconfigurable members extend horizontally into the interior space of the housing, and the one or more reconfigurable members are configured to attach to the housing at an adjustable vertical position, the adjustable vertical position being selected based on a dimension of the first component.
Clause 3. The chassis adapter of clause 2, wherein the one or more reconfigurable members are configured to enable the adjustable vertical position to accommodate the first component having a non-standard dimension.
Clause 4. The chassis adapter of any of clause 1 through clause 3, wherein the one or more reconfigurable members are configured to accommodate the first component being arranged with a long dimension in the vertical direction and the first component being stacked vertically with respect to a second component that is mounted in the interior space.
Clause 5. The chassis adapter of any of clause 1 through clause 4, wherein the one or more reconfigurable members are cantilevered from an interior wall of the housing.
Clause 6. The chassis adapter of any of clause 1 through clause 5, wherein the one or more reconfigurable members extend from a first vertical wall of the housing to a second vertical wall of the housing, and the one or more reconfigurable members attaches to the first vertical wall and to the second vertical wall.
Clause 7. The chassis adapter of any of clause 1 through clause 6, wherein the one or more reconfigurable members are configured to attach to a vertical position along the housing such that the vertical position is one of a plurality of discrete locations in the vertical direction along a wall of the housing.
Clause 8. The chassis adapter of any of clause 1 through clause 7, wherein the one or more reconfigurable members are configured to attach to a vertical position along the housing such that the vertical position is one of a continuum of locations in the vertical direction along a wall of the housing.
Clause 9. The chassis adapter of any of clause 2 through clause 8, wherein the one or more reconfigurable members provide one or more guides that fix a horizontal position at which the first component is mounted with respect to the chassis adapter.
Clause 10. The chassis adapter of any of clause 1 through clause 9, further comprising: an electrical busbar fixed to the chassis adapter and configured to receive electrical power and provide the electrical power to the first component, the electrical busbar including power ports arranged in a horizontal direction.
Clause 11. The chassis adapter of any of clause 1 through clause 10, further comprising: a coolant manifold configured to receive a coolant and provide the coolant to the first component, the coolant manifold including coolant ports arranged in a horizontal direction.
Clause 12. A method for using a chassis adapter to adapt a standardized rack, the method comprising: attaching a housing of the chassis adapter to standardized attach points of the standardized rack, the housing having an interior space configured to provide an adaptable mounting of components including a first component; attaching, to the housing, one or more reconfigurable members extending into the interior space of the housing, the one or more reconfigurable members providing adjustable attach points for the first component with respect to the housing; and attaching the first component to the housing via the one or more reconfigurable members.
Clause 13. The method of clause 12, wherein: the one or more reconfigurable members provide attach points for the first component to be vertically mounted in the interior space with a long axis of the first component in a vertical direction, the one or more reconfigurable members extend horizontally into the interior space of the housing, and the one or more reconfigurable members are configured to attach to the housing at an adjustable vertical position, the adjustable vertical position being selected based on a dimension of the first component.
Clause 14. The method of clause 13, wherein the one or more reconfigurable members are configured to enable the adjustable vertical position to accommodate the first component having a non-standard dimension.
Clause 15. The method of any of clause 12 through clause 14, wherein the one or more reconfigurable members are configured to accommodate the first component being arranged with a long dimension in a vertical direction and the first component being stacked vertically with respect to a second component that is mounted in the interior space.
Clause 16. The method of any of clause 12 through clause 15, wherein: the one or more reconfigurable members are cantilevered from an interior wall of the housing, or the one or more reconfigurable members extend from a first vertical wall of the housing to a second vertical wall of the housing, and the one or more reconfigurable members attaches to the first vertical wall and to the second vertical wall.
Clause 17. The method of any of clause 12 through clause 16, wherein the one or more reconfigurable members are configured to attach to a vertical position along the housing such that the vertical position is one of a plurality of discrete locations in the vertical direction along a wall of the housing.
Clause 18. The method of any of clause 12 through clause 17, wherein the one or more reconfigurable members are configured to attach to a vertical position along the housing such that the vertical position is one of a continuum of locations in the vertical direction along a wall of the housing.
Clause 19. The method of any of clause 13 through clause 18, wherein the one or more reconfigurable members provide one or more guides that fix a horizontal position at which the first component is mounted with respect to the chassis adapter.
Clause 20. The method of any of clause 12 through clause 19, the method further comprising: connecting the first component to receive electrical power from an electrical busbar, the electrical busbar being fixed to the chassis adapter and having electrical ports arranged in a horizontal direction; and connecting the first component to receive coolant from a coolant manifold, the coolant manifold being fixed to the chassis adapter and having coolant ports arranged in a horizontal direction.

What is claimed is:

1. A chassis adapter for adapting a standardized rack, comprising:
a housing that includes a front plate and an interior space, the front plate being configured to attach to standardized attachment points of the standardized rack, and the interior space being configured to provide an adaptable arrangement for component mounting; and
one or more reconfigurable members extending into the interior space of the housing, the one or more reconfigurable members providing adjustable attach points for a first component with respect to the housing, the first component being mounted in the interior space of the housing.

2. The chassis adapter of claim 1, wherein:
the one or more reconfigurable members provide attach points for the first component to be vertically mounted in the interior space,
the one or more reconfigurable members extend horizontally into the interior space of the housing, and
the one or more reconfigurable members are configured to attach to the housing at an adjustable vertical position, the adjustable vertical position being selected based on a dimension of the first component.

3. The chassis adapter of claim 2, wherein the one or more reconfigurable members are configured to enable the adjustable vertical position to accommodate the first component having a non-standard dimension.

4. The chassis adapter of claim 1, wherein the one or more reconfigurable members are configured to accommodate the first component being arranged with a long dimension in a vertical direction and the first component being stacked vertically with respect to a second component that is mounted in the interior space.

5. The chassis adapter of claim 1, wherein the one or more reconfigurable members are cantilevered from an interior wall of the housing.

6. The chassis adapter of claim 1, wherein the one or more reconfigurable members extend from a first vertical wall of the housing to a second vertical wall of the housing, and the one or more reconfigurable members attaches to the first vertical wall and to the second vertical wall.

7. The chassis adapter of claim 1, wherein the one or more reconfigurable members are configured to attach to a vertical position along the housing such that the vertical position is one of a plurality of discrete locations in a vertical direction along a wall of the housing.

8. The chassis adapter of claim 1, wherein the one or more reconfigurable members are configured to attach to a vertical position along the housing such that the vertical position is one of a continuum of locations in a vertical direction along a wall of the housing.

9. The chassis adapter of claim 2, wherein the one or more reconfigurable members provide one or more guides that fix a horizontal position at which the first component is mounted with respect to the chassis adapter.

10. The chassis adapter of claim 1, further comprising:
an electrical busbar fixed to the chassis adapter and configured to receive electrical power and provide the electrical power to the first component, the electrical busbar including power ports arranged in a horizontal direction.

11. The chassis adapter of claim 1, further comprising:
a coolant manifold configured to receive a coolant and provide the coolant to the first component, the coolant manifold including coolant ports arranged in a horizontal direction.

12. A method for using a chassis adapter to adapt a standardized rack, the method comprising:
attaching a housing of the chassis adapter to standardized attachment points of the standardized rack, the housing having an interior space configured to provide an adaptable mounting of components including a first component;
attaching, to the housing, one or more reconfigurable members extending into the interior space of the housing, the one or more reconfigurable members providing adjustable attach points for the first component with respect to the housing; and
attaching the first component to the housing via the one or more reconfigurable members.

13. The method of claim 12, wherein:
the one or more reconfigurable members provide attach points for the first component to be vertically mounted in the interior space with a long axis of the first component in a vertical direction,
the one or more reconfigurable members extend horizontally into the interior space of the housing, and
the one or more reconfigurable members are configured to attach to the housing at an adjustable vertical position, the adjustable vertical position being selected based on a dimension of the first component.

14. The method of claim 13, wherein the one or more reconfigurable members are configured to enable the adjustable vertical position to accommodate the first component having a non-standard dimension.

15. The method of claim 12, wherein the one or more reconfigurable members are configured to accommodate the first component being arranged with a long dimension in a vertical direction and the first component being stacked vertically with respect to a second component that is mounted in the interior space.

16. The method of claim 12, wherein:
the one or more reconfigurable members are cantilevered from an interior wall of the housing, or
the one or more reconfigurable members extend from a first vertical wall of the housing to a second vertical wall of the housing, and the one or more reconfigurable members attaches to the first vertical wall and to the second vertical wall.

17. The method of claim 12, wherein the one or more reconfigurable members are configured to attach to a vertical position along the housing such that the vertical position is one of a plurality of discrete locations in a vertical direction along a wall of the housing.

18. The method of claim 12, wherein the one or more reconfigurable members are configured to attach to a vertical position along the housing such that the vertical position is one of a continuum of locations in a vertical direction along a wall of the housing.

19. The method of claim 13, wherein the one or more reconfigurable members provide one or more guides that fix a horizontal position at which the first component is mounted with respect to the chassis adapter.

20. The method of claim 12, the method further comprising:
connecting the first component to receive electrical power from an electrical busbar, the electrical busbar being fixed to the chassis adapter and having electrical ports arranged in a horizontal direction; and
connecting the first component to receive coolant from a coolant manifold, the coolant manifold being fixed to the chassis adapter and having coolant ports arranged in a horizontal direction.
